(19) United States
(12) Patent Application Publication
(10) Pub. No.: US 2024/0120236 A1
(43) Pub. Date: Apr. 11, 2024

(54) Isolation Regions For Isolating Transistors and the Methods Forming the Same

(71) Applicant: Taiwan Semiconductor Manufacturing Co., Ltd., Hsinchu (TW)

(72) Inventors: Tai-Jung Kuo, Hsinchu (TW); Po-Cheng Shih, Hsinchu (TW); Wan Chen Hsieh, Hsinchu (TW); Zhen-Cheng Wu, Hsinchu (TW); Chia-Hui Lin, Dajia Township (TW); Tze-Liang Lee, Hsinchu (TW)

(21) Appl. No.: 18/306,716

(22) Filed: Apr. 25, 2023

Related U.S. Application Data
(60) Provisional application No. 63/481,007, filed on Jan. 23, 2023.
(60) Provisional application No. 63/378,691, filed on Oct. 7, 2022.

(51) Int. Cl. H01L 21/762; H01L 21/02; H01L 21/8234; H01L 27/088

(52) U.S. Cl. CPC H01L 21/76224; H01L 21/02164; H01L 21/02211; H01L 21/02274; H01L 21/0228; H01L 21/02304; H01L 21/02315; H01L 21/823481; H01L 27/0886

(57) ABSTRACT

A method includes etching a gate stack in a wafer to form a trench, depositing a silicon nitride liner extending into the trench, and depositing a silicon oxide layer. The process of depositing the silicon oxide layer includes performing a treatment process on the wafer using a process gas including nitrogen and hydrogen, and performing a soaking process on the wafer using a silicon precursor.

### PRIORITY CLAIM AND CROSS-REFERENCE

This application claims the benefit of the following provisionally filed U.S. patent applications: Application No. 63/481,007, filed on Jan. 23, 2023, and entitled “Method of Manufacturing Cut Metal Gate,” and Application No. 63/378,691, filed on Oct. 7, 2022, and entitled “Gradient and Seam-Free Structure Oxide Insulator in Metal Gate Boundary Isolation,” which applications are hereby incorporated herein by reference.

### BACKGROUND

Technological advances in Integrated Circuit (IC) materials and design have produced generations of ICs where each generation has smaller and more complex circuits than the previous generations. In the course of IC evolution, functional density (for example, the number of interconnected devices per chip area) has generally increased while geometry sizes have decreased. This scaling down process generally provides benefits by increasing production efficiency and lowering associated costs.

Such scaling down has also increased the complexity of processing and manufacturing ICs, and for these advances to be realized, similar developments in IC processing and manufacturing are needed. For example, Fin Field-Effect Transistors (FinFETs) have been introduced to replace planar transistors. The structures of FinFETs and methods of fabricating FinFETs are being developed.

The formation of FinFETs may include forming long semiconductor fins and long gate stacks, and then forming dielectric regions to cut the long semiconductor fins and long gate stacks into shorter portions, so that the shorter portions may act as the fins and the gate stacks of the FinFETs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-8, 9A, 9B, 9C, 10-21, 22A, 22B, and 22C illustrate the cross-sectional views, perspective views, and top views of intermediate stages in the formation of Fin Field-Effect Transistors (FinFETs) and isolation regions in accordance with some embodiments.

FIG. 23 illustrates a chemical structure of a silicon-containing precursor in accordance with some embodiments.

FIG. 24 illustrates a process flow for forming FinFETs in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A method of forming isolation regions for electrically isolating transistors is provided. In accordance with some embodiments, gate stacks are formed for Fin Field-Effect Transistors (FinFETs). Gate isolation regions (also referred to as Cut-Metal-Gate (CMG) regions) are formed to cut the long gate stacks into shorter portions. The formation of the gate isolation regions includes etching the gate stacks to form trenches, forming a silicon nitride liner extending into the trenches, and depositing silicon oxide on the silicon nitride liner. The deposition of silicon oxide may be performed using Plasma Enhanced Atomic Layer Deposition (PEALD), wherein an ammonia plasma treatment process, a silicon precursor soaking process, and an oxidation process are performed. The ammonia plasma treatment process is controlled so that silicon oxide is deposited faster at lower parts of the trenches than at upper parts of the trenches, so that silicon oxide is deposited in a bottom-up style. The resulting CMG regions are seam-free.

In the illustrated embodiments, the formation of Fin Field-Effect Transistors (FinFETs) is used as an example to explain the concept of the present disclosure. Other types of transistors such as planar transistors, Gate-All-Around (GAA) transistors, or the like may also adopt the concept of the present disclosure. Also, the formation of isolation regions may be used in other trench-filling processes other than the formation of CMG regions. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

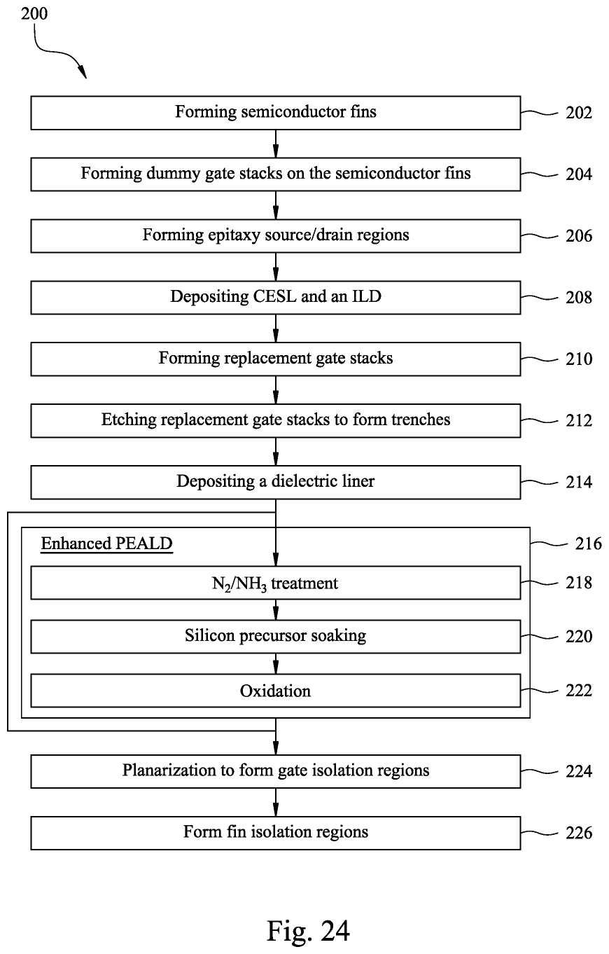

1-8, 9A, 9B, 9C, 10-21, 22A, 22B, and 22C illustrate the perspective views, top views, and cross-sectional views of intermediate stages in the formation of FinFETs in accordance with some embodiments. The respective processes are also reflected schematically in the process flow 200 as shown in FIG. 24.

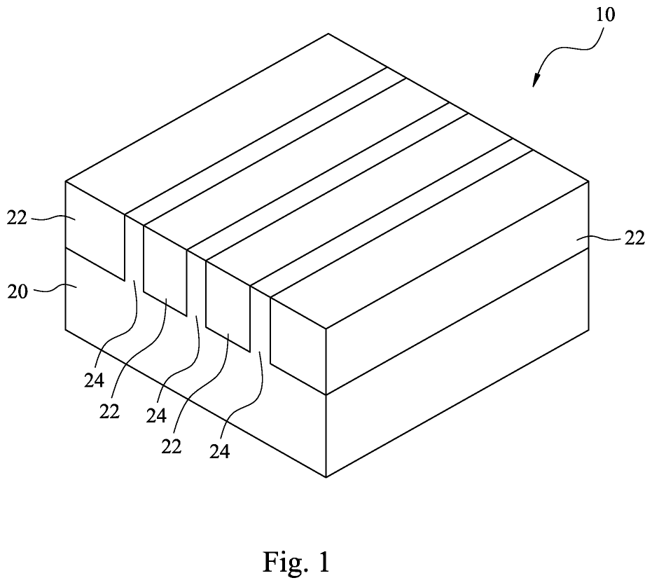

FIG. 1 illustrates a perspective view of an initial structure. The initial structure includes wafer 10, which further includes substrate 20. Substrate 20 may be a semiconductor substrate, which may be a silicon substrate, a silicon germanium substrate, or a substrate formed of other semiconductor materials. Substrate 20 may be doped with a p-type or an n-type impurity. Isolation regions 22 such as Shallow Trench Isolation (STI) regions may be formed to extend from a top surface of substrate 20 into substrate 20. The portions of substrate 20 between neighboring STI regions 22 are referred to as semiconductor strips 24. The top surfaces of semiconductor strips 24 and the top surfaces of STI regions 22 may be substantially level with each other in accordance with some embodiments.

In accordance with some embodiments, semiconductor strips 24 are parts of the original substrate 20, and hence the material of semiconductor strips 24 is the same as that of substrate 20. In accordance with alternative embodiments of the present disclosure, semiconductor strips 24 are replacement strips formed by etching the portions of substrate 20 between STI regions 22 to form recesses, and performing an epitaxy to regrow another semiconductor material in the recesses. Accordingly, semiconductor strips 24 are formed of a semiconductor material different from that of substrate 20. In accordance with some embodiments, semiconductor strips 24 are formed of silicon germanium, carbon-doped silicon, a III-V compound semiconductor material, or the like.

STI regions 22 may include a liner oxide (not shown), which may be a thermal oxide formed through a thermal oxidation of a surface layer of substrate 20. The liner oxide may also be a deposited silicon oxide layer formed using, for example, Atomic Layer Deposition (ALD), High-Density Plasma Chemical Vapor Deposition (HDPCVD), Chemical Vapor Deposition (CVD), or the like. STI regions 22 may also include a dielectric material over the liner oxide, wherein the dielectric material may be formed using Flowable Chemical Vapor Deposition (FCVD), spin-on coating, or the like.

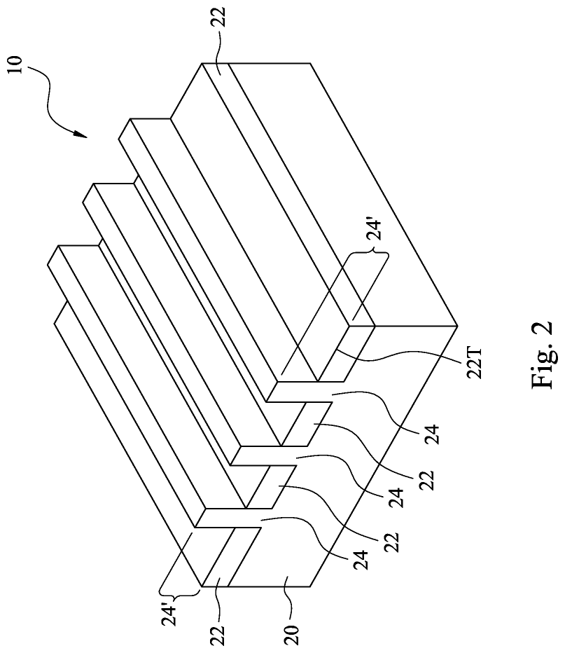

Referring to FIG. 2, STI regions 22 are recessed, so that the top portions of semiconductor strips 24 protrude higher than the top surfaces 22T of the remaining portions of STI regions 22 to form protruding semiconductor fins 24′. The respective process is illustrated as process 202 in the process flow 200 as shown in FIG. 24. The etching may be performed using a dry etching process, wherein HF and NH₃, for example, may be used as the etching gases. During the etching process, plasma may be generated. Argon may also be included. In accordance with alternative embodiments of the present disclosure, the recessing of STI regions 22 is performed using a wet etch process. The etching chemical may include HF, for example.

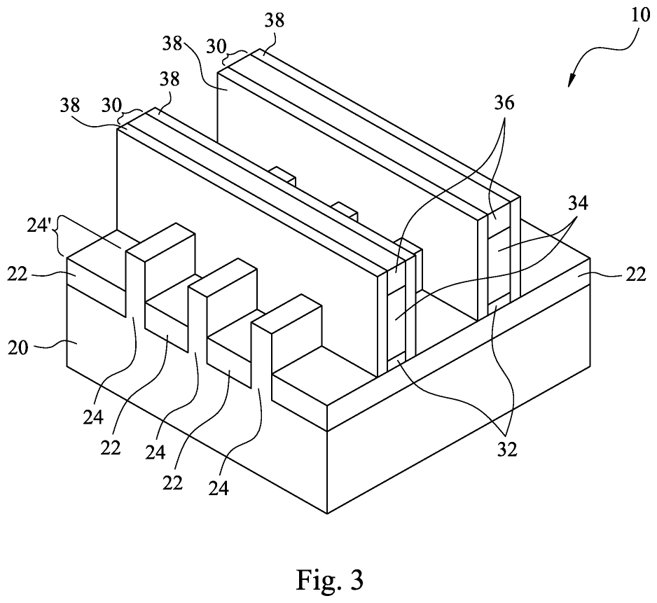

Referring to FIG. 3, dummy gate stacks 30 are formed on the top surfaces and the sidewalls of (protruding) fins 24′. The respective process is illustrated as process 204 in the process flow 200 as shown in FIG. 24. Dummy gate stacks 30 may include dummy gate dielectrics 32 and dummy gate electrodes 34 over dummy gate dielectrics 32. Dummy gate dielectrics 32 may be formed of or comprise silicon oxide. Dummy gate electrodes 34 may be formed, for example, using polysilicon or amorphous silicon, and other materials may also be used. Each of dummy gate stacks 30 may also include one (or a plurality of) hard mask layer 36 over dummy gate electrodes 34. Hard mask layers 36 may be formed of silicon nitride, silicon oxide, silicon carbo-nitride, or multi-layers thereof. Dummy gate stacks 30 may cross over a plurality of protruding semiconductor fins 24′ and STI regions 22.

Next, gate spacers 38 are formed on the sidewalls of dummy gate stacks 30. In accordance with some embodiments, gate spacers 38 are formed of a dielectric material such as silicon nitride, silicon carbo-nitride, or the like, and may have a single-layer structure or a multi-layer structure including a plurality of dielectric layers.

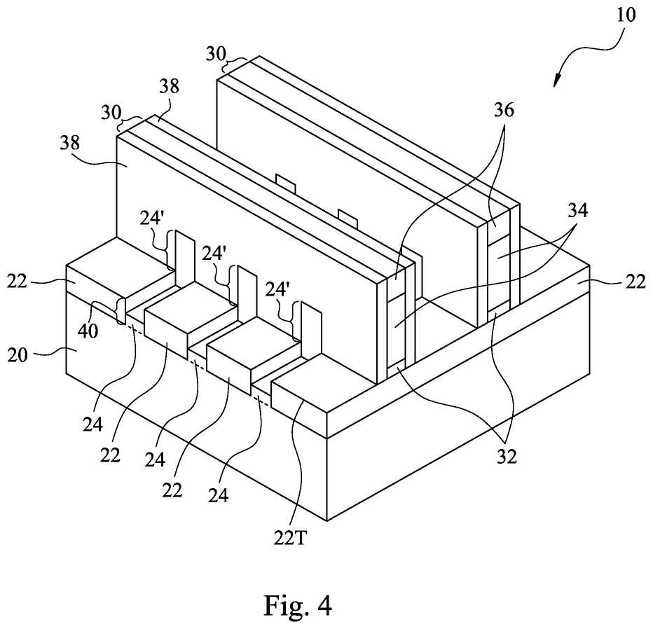

A recessing process is then performed to etch the portions of protruding semiconductor fins 24′ that are not covered by dummy gate stacks 30 and gate spacers 38, resulting in the structure shown in FIG. 4. The recessing may be anisotropic, and hence the portions of fins 24′ directly underlying dummy gate stacks 30 and gate spacers 38 are protected, and are not etched. The top surfaces of the recessed semiconductor strips 24 may be lower than the top surfaces 22T of STI regions 22 in accordance with some embodiments. Recesses 40 are accordingly formed between STI regions 22. Recesses 40 are located on the opposite sides of dummy gate stacks 30.

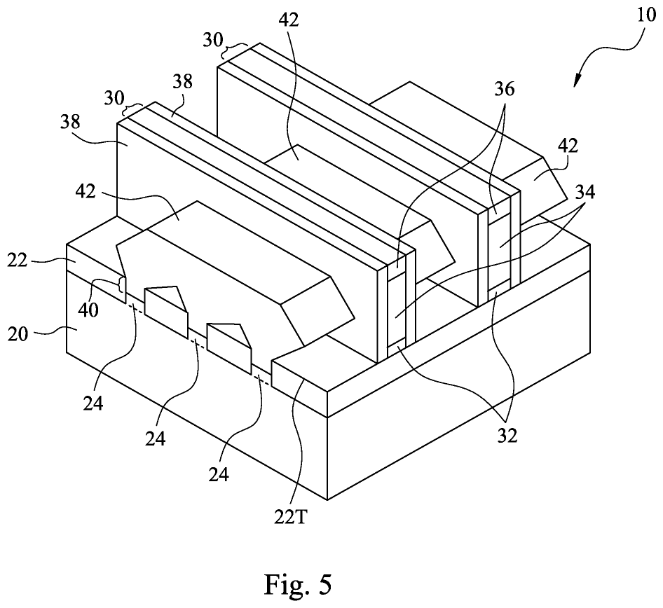

Next, epitaxy regions (source/drain regions) 42 are formed by selectively growing a semiconductor material from recesses 40, resulting in the structure in FIG. 5. The respective process is illustrated as process 206 in the process flow 200 as shown in FIG. 24. Source/drain region(s) may refer to a source or a drain, individually or collectively dependent upon the context. In accordance with some embodiments, epitaxy regions 42 include silicon germanium, carbon-doped silicon, or silicon. Depending on whether the resulting FinFET is a p-type FinFET or an n-type FinFET, a p-type or an n-type impurity may be in-situ doped with the proceeding of the epitaxy process. For example, when the resulting FinFET is a p-type FinFET, silicon germanium boron (SiGeB) may be grown. Conversely, when the resulting FinFET is an n-type FinFET, silicon phosphorous (SiP) or silicon carbon phosphorous (SiCP) may be grown. After epitaxy regions 42 fully fill recesses 40, epitaxy regions 42 start expanding horizontally, and facets may be formed.

After the epitaxy process, epitaxy regions 42 may be further implanted with a p-type or an n-type impurity to form source and drain regions, which are also denoted using reference numeral 42. In accordance with alternative embodiments of the present disclosure, the implantation process is skipped when epitaxy regions 42 are in-situ doped with the p-type or n-type impurity during the epitaxy to form source/drain regions. Epitaxy source/drain regions 42 include lower portions that are formed in STI regions 22, and upper portions that are formed over the top surfaces of STI regions 22.

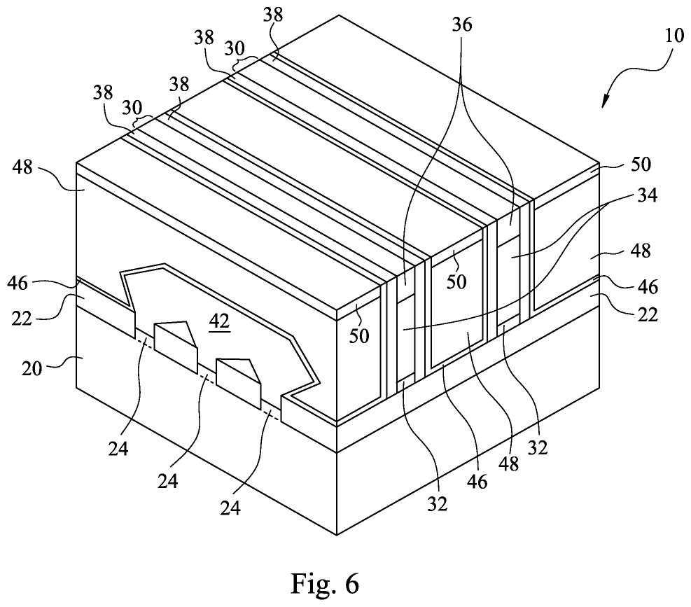

FIG. 6 illustrates a perspective view of the structure after the formation of Contact Etch Stop Layer (CESL) 46 and Inter-Layer Dielectric (ILD) 48. The respective process is illustrated as process 208 in the process flow 200 as shown in FIG. 24. CESL 46 may be formed of silicon nitride, silicon carbo-nitride, or the like. CESL 46 may be formed using a conformal deposition method such as ALD or CVD, for example. ILD 48 may include a dielectric material formed using, for example, FCVD, spin-on coating, CVD, or another deposition method. ILD 48 may also be formed of an oxygen-containing dielectric material, which may be a silicon-oxide based material such as silicon oxide, Phospho-Silicate Glass (PSG), Boro-Silicate Glass (BSG), Boron-Doped Phospho-Silicate Glass (BPSG), or the like. A planarization process such as a Chemical Mechanical Polish (CMP) process or a mechanical grinding process is performed to level the top surfaces of ILD 48, dummy gate stacks 30, and gate spacers 38 with each other.

FIG. 6 also illustrates the formation of hard masks 50, which are used for protecting ILD 48 in subsequent processes. In accordance with some embodiments, the formation of hard mask 50 includes recessing ILD 48 (and possibly CESL 46) to form recesses between neighboring gate spacers 38, filling a dielectric layer to fill the recesses, and performing a planarization process (such as CMP process or a mechanical grinding process) to remove excess portions of the dielectric material. The remaining portions of the dielectric material are hard masks 50. In accordance with some embodiments, hard masks 50 are formed of or comprise silicon nitride, silicon oxynitride, or the like.

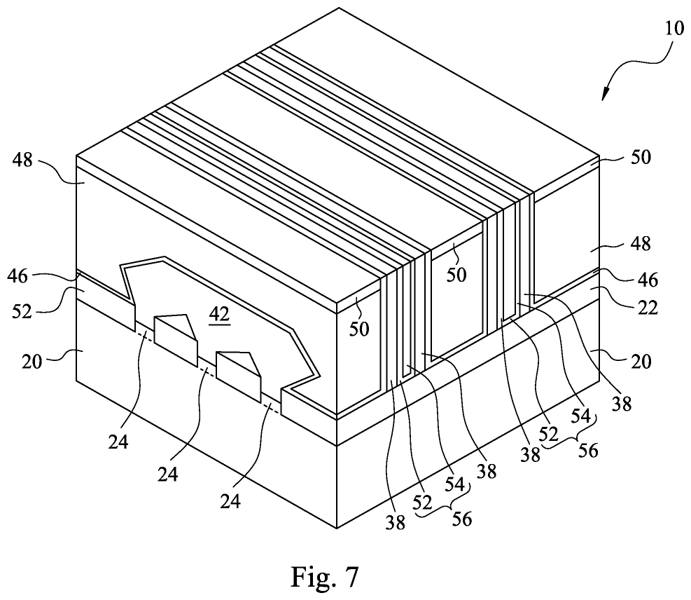

FIG. 7 illustrates the formation of replacement gate stacks 56. The respective process is illustrated as process 210 in the process flow 200 as shown in FIG. 24. The formation process includes removing the dummy gate stacks 30 to form trenches, and forming replacement gate stacks 56 in the resulting trenches. Gate stacks 56 include gate dielectrics 52 and gate electrodes 54. Gate dielectrics 52 may include interfacial layers and high-k dielectric layers over the interfacial layers. The interfacial layers may include silicon oxide. The high-k dielectric layers may include hafnium oxide, zirconium oxide, lanthanum oxide, and/or the like. Gate electrodes 54 may include work function layers comprising TiN, TiSiN, TaN, TiAlN, TiAl, and/or the like, and may or may not include filling metals comprising cobalt, tungsten, and/or the like. Accordingly, gate electrodes 54 are also referred to as metal gates 54.

Next, the formation process proceeds to the formation of gate isolation regions (also sometime referred to as CMG regions) for separating gate stacks 56 into shorter portions. The respective processes are referred to as CMG processes. It is appreciated that in the illustrated example embodiments, replacement gate stacks are cut. In accordance with alternative embodiments, dummy gate stacks may be cut, and the formation of the gate isolation regions may be performed before replacing the dummy gate stacks 30 with replacement gate stacks 56.

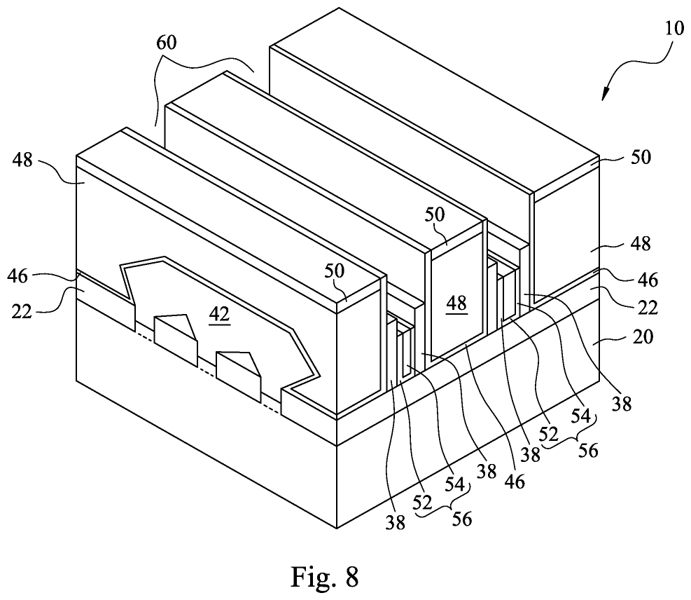

Referring to FIG. 8, replacement gate stacks 56 are recessed through etching processes to form recesses 60, so that the height of replacement gate stacks 56 is reduced. In the etching process, hard masks 50 protect the underlying ILD 48. In accordance with some embodiments, gate spacers 38 may also be recessed. In accordance with alternative embodiments, gate spacers 38 are not recessed.

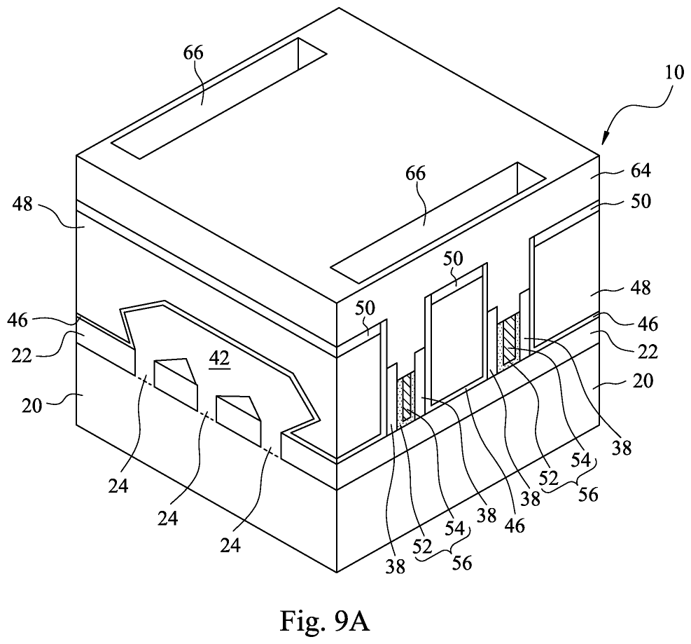

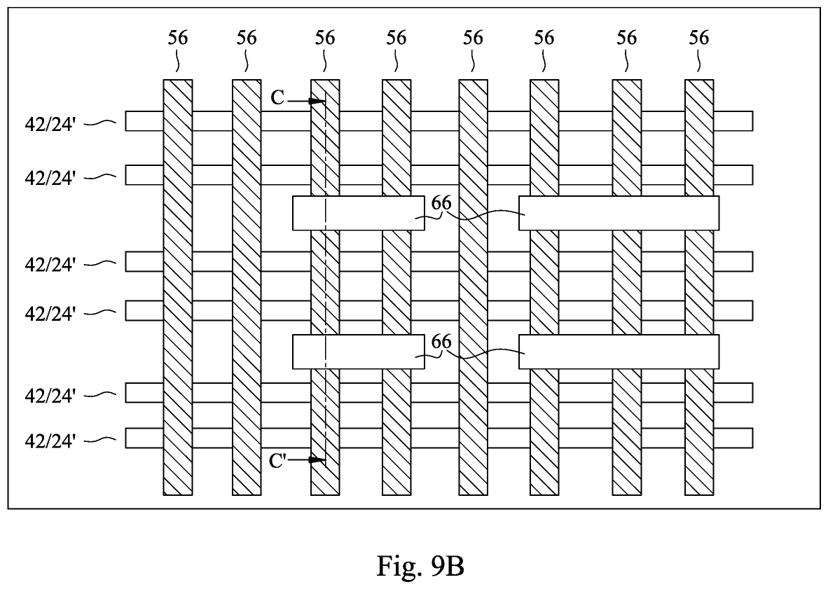

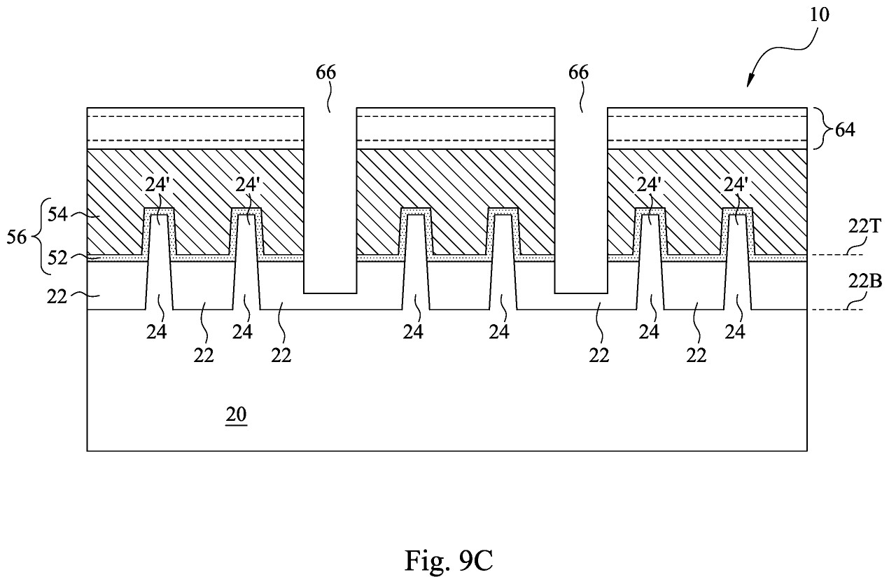

Referring to FIG. 9A, hard mask 64 is formed. The formation process may include depositing a hard mask layer(s), and performing a planarization process such as a CMP process or a mechanical grinding process to level the top surface of hard mask 64. Hard mask 64 extends into recesses 60 as shown in FIG. 8. In accordance with some embodiments, hard mask 64 is formed of a homogeneous material such as amorphous silicon. In accordance with alternative embodiments, hard mask 64 may be a composite layer including a plurality of layers. For example, hard mask layer 64 may include a first layer (which may be a conformal layer) and a second layer over the first layer. The first layer may be formed of or comprise silicon nitride, while the second layer may include amorphous silicon in accordance with some embodiments. Hard mask 64 may or may not include a third layer such as a silicon nitride layer deposited on the planarized second layer.

Next, as shown in FIGS. 9A, 9B, and 9C, an etching process is performed. The etching process may include forming an etching mask (such as a photoresist or a tri-layer etching mask, not shown), patterning the etching mask, and etching hard masks 64 and 50, ILD 48, CESL 46, and replacement gate stack 56 to form trenches 66. The respective process is illustrated as process 212 in the process flow 200 as shown in FIG. 24.

FIG. 9B illustrates a top view of a structure including a plurality of gate stacks 56, wherein FIGS. 9A and 9C illustrate a perspective view and a cross-sectional view, respectively of a portion of the structure in FIG. 9B. The plurality of protruding semiconductor fins 24′ as shown in FIG. 9B are directly underlying gate stacks 56, and source/drain regions 42 are between neighboring gate stacks 56. It is appreciated that although not shown in FIG. 9B, a merged source/drain region(s) may be formed based on any number of fins. For example, FIG. 9A illustrates an example in which source/drain region 42 may be formed based on three protruding semiconductor fins 24′. In FIG. 9B, on the other hand, the source/drain regions 42 formed based on two protruding semiconductor fins 24 may be merged, and the merged portions are not shown.

Referring to FIG. 9C, which illustrates the cross-section C-C′ in FIG. 9B, replacement gate stacks 56 are cut apart into separate portions. In accordance with some embodiments, after the etching-through of gate stacks 56, STI regions 22 may be recessed, so that trenches 66 extend into STI regions 22. In accordance with alternative embodiments, the formation of trenches 66 is stopped on the top surfaces of STI regions 22.

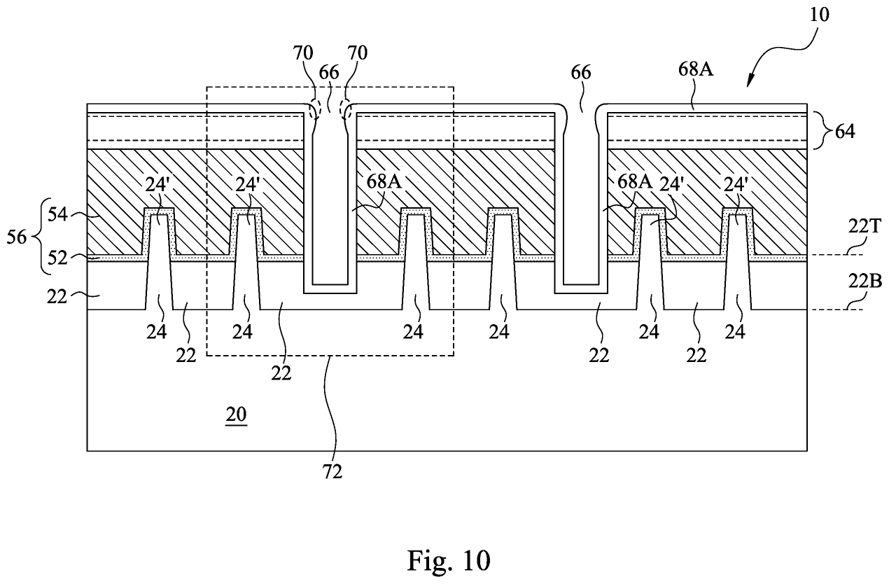

Referring to FIG. 10, dielectric liner 68A is deposited and lining trenches 66. The respective process is illustrated as process 214 in the process flow 200 as shown in FIG. 24. Dielectric liner 68A may be formed of or comprise silicon nitride, and dielectric liner 68A may be, or may not be, free from other elements such as oxygen. The precursors for forming silicon nitride may include a nitrogen-containing precursor (also referred to as a nitrogen precursor) such as NH₃, N₂, and/or the like, and a silicon-containing precursor (also referred to as a silicon precursor) such as silane (SiH₄), disilane (Si₂H₄), DiChloroSilane (DCS, SiH₂Cl₂), and/or the like.

In accordance with some embodiments, dielectric liner 68A may be formed using Plasma Enhanced Atomic Layer Deposition (PEALD). The formation process may include a plurality of PEALD cycles. Each of the PEALD cycles may include pulsing the silicon precursor, turning on and then turning off plasma, purging the silicon precursor, pulsing the nitrogen precursor, turning on and then turning off plasma, and purging the nitrogen precursor. In accordance with alternative embodiments, thermal Atomic Layer Deposition (ALD), CVD, or the like, may be used for forming the dielectric liner 68A.

The PEALD has the tendency of generating overhangs. For example, FIG. 10 illustrates overhangs 70. The overhangs may adversely affect the subsequent filling of trenches, and cause seams to be generated in the resulting CMG regions. This problem is addressed by the embodiments of the present disclosure.

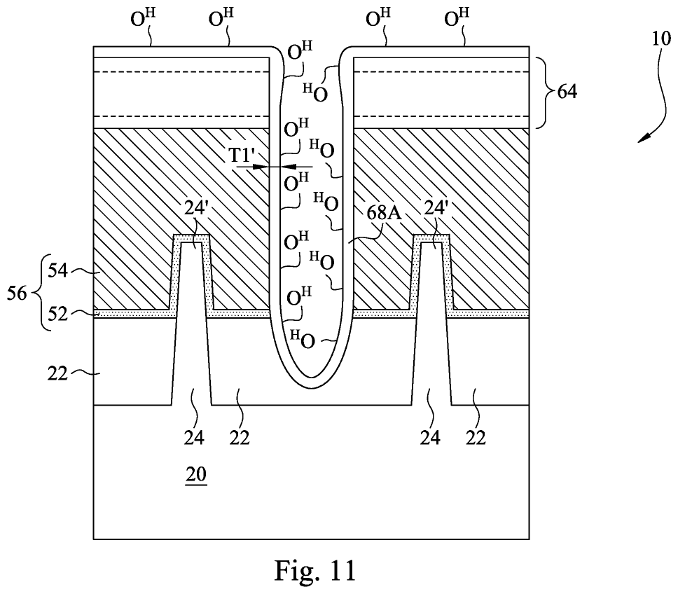

FIGS. 11-18 illustrate the magnified views of intermediate stages in the filling of trenches with dielectric filling-region 68B. The magnified views are obtained from the region 72 in FIG. 10. FIG. 11 illustrates the formation of dielectric liner 68A, as discussed in preceding paragraphs. In accordance with some embodiments, due to the formation of native oxide and the exposure to moisture, the surface of dielectric liner 68A is oxidized, and Si—OH bonds are formed at the surface of dielectric liner 68A. FIG. 11 illustrates some example OH groups, which are bonded to the silicon atoms in dielectric liner 68A. The OH groups are attached throughout the exposed surface of dielectric liner 68A.

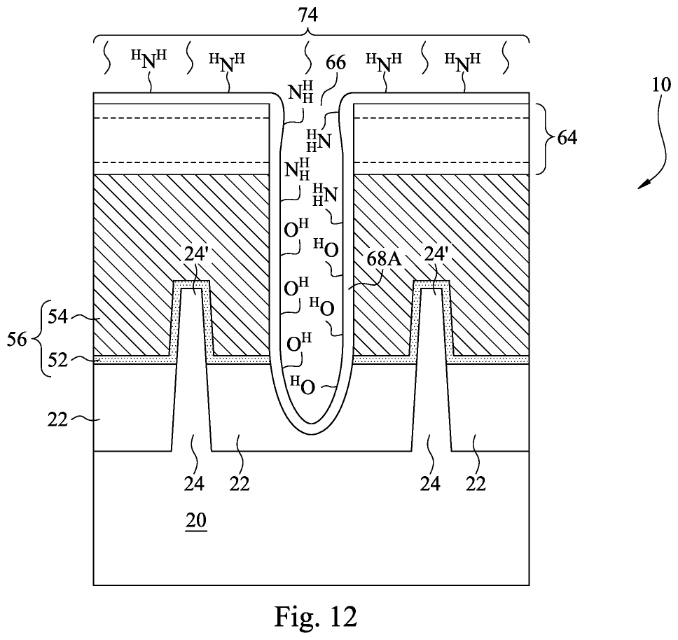

FIGS. 12 through 14 illustrate an enhanced PEALD cycle, in which a silicon oxide layer is deposited. The respective process is illustrated as process 216 in the process flow 200 as shown in FIG. 24. The deposition of silicon oxide is selective, with the deposition rates of silicon oxide in lower parts of trenches 66 being greater than the deposition rates of silicon oxide in the respective upper parts of trenches 66.

Referring to FIG. 12, treatment process 74 is performed to attach NHₓ groups (such as NH₂ groups) to the surface of dielectric liner 68A. The respective process is illustrated as process 218 in the process flow 200 as shown in FIG. 24. The NH₂ groups are attached where the OH group is broken off from the silicon in dielectric liner 68A. The treatment process 74 is performed by generating plasma from the process gas, so that the OH groups can be detached from silicon. In accordance with some embodiments, treatment process 74 is performed using a process gas comprising NH₃, and other gases such as nitrogen (N₂) and an inert gas such as argon may be, or may not be, added. In accordance with alternative embodiments, treatment process 74 is performed using a process gas comprising nitrogen (N₂), and an inert gas such as argon may be, or may not be, added into the process gas.

When N₂ is used without the addition of NH₃, the following reaction equation may occur:

—OH+N₂^{*/+}<-->O^{*}+N₂H^{*/+}_{(g or s)}<-->—NHₓ+H₂O_{(g)} [Eq. 1]

When NH₃ is used without the addition of N₂, NH₂ ions/radicals NH₂^{*/+} and hydron ions/radicals H^{*/+} are generated, and the following reaction equation may occur:

—OH+NH₂^{*/+}/H^{*/+}<-->O^{*}+N₂H^{*/+}_{(g or s)}<-->—NHₓ+H₂O_{(g)} [Eq. 2]

The NH₃ gas, or the mixture of NH₃ and N₂ gas are more readily dissociated than N₂ alone is used as the process, leading to more active species. Accordingly, N₂ gas may be used for the treatment process 74, while NH₃ may make the treatment process 74 more efficient. For example, the concentration of NH₂ may be increased significantly when NH₃ is used as the process gas, and hence more of the OH groups on the surface of dielectric liner 68A may be replaced with NH₂.

It is appreciated that it is more difficult for the NH₂ groups to reach deep into trenches 66 than to reach the upper portions of trenches 66. Accordingly, the upper portions of dielectric liner 68A in trenches 66 and the portions of dielectric liner 68A outside of trenches 66 have higher replacing rates than the corresponding lower portions of dielectric liner 68A deeper into trenches 66. Throughout the description, the term “replacing rate” represents the percentage of the OH groups replaced with NHₓ groups such as NH₂. With the proceeding of the treatment time, the top surface of the horizontal portions of dielectric liner 68A may be fully replaced (with over 90 or 95 percent replacing rate, for example).

In accordance with some embodiments, as shown in FIG. 12, treatment process 74 is controlled, so that the difference between the replacing rate at the bottom and the replacing rate at the top of trenches 66 are as great as possible. When the OH groups attached to the top surface of the horizontal portions of dielectric liner 68A are substantially fully replaced with NH₂ groups, at the bottom of trenches 66, the replacing rates are as low as possible, such as lower than about 50 percent, lower than about 20 percent, lower than about 10 percent, or lower. From the bottom of trenches 66 to the top of trenches 66, the replacing rates increase gradually, and may be continuously.

To achieve the aforementioned large difference in the replacing rates between the top and the bottom of trenches 66, process conditions are controlled. For example, the chamber pressure of the respective treatment chamber may be increased, so that mean-free-path of the ions and radicals are reduced, and hence it is more difficult for the plasma to reach the bottom of trenches when it can reach the top parts of dielectric liner 68A easily. For example, the chamber pressure may be in the range between about 0.5 Torr and about 10 Torr. It is appreciated that the process conditions are related to the specific structure of wafer 10 such as the aspect ratios, the depths, the widths, and the density of trenches 66. Different structures of wafer 10 may have different optimum process conditions, which may be found through experiments.

Also, the treatment process 74 may be performed with a high radio-frequency power in the range between about 15 Watts and about 1,000 watts. The flow rate of NH₃ may be greater than 0 L/minute and lower than about 5 L/minute. The flow rate of N₂ may be in the range between about (including) 0 L/minute and about 5 L/minute. The flow rate of argon may be in the range between about 2 L/minute and about 10 L/minute.

In addition, if treatment process 74 is prolonged, the replacing rates will increase over the treatment time until substantially full replacement (even at the bottom of trenches 66) is reached. At which time, the replacing is saturated. Accordingly, to prevent the full replacement from happening, and to achieve the large difference between the replacing rate at the top and the replacing rate at the bottom of trenches 66, treatment process 74 is stopped as soon as the OH groups at the top surface of dielectric liner 68A are substantially fully replaced. At which time, the OH groups at the bottom part of dielectric liner 68A is still minimum (such as lower than about 50 percent, about 20 percent, or about 10 percent), and may be unreplaced or substantially unreplaced in accordance with some embodiments.

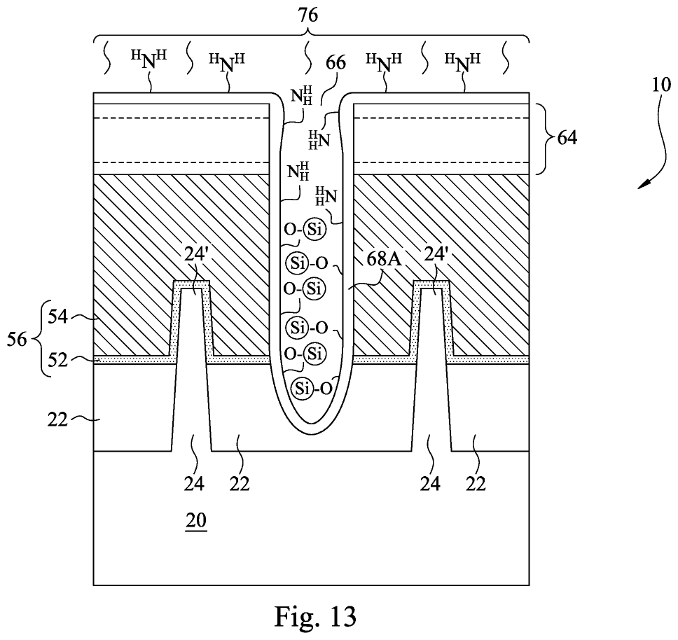

Referring to FIG. 13, a soaking process 76 is performed, wherein wafer 10 is soaked in a silicon precursor. The respective process is illustrated as process 220 in the process flow 200 as shown in FIG. 24. The silicon precursor may comprise an aminosilane precursor, which may comprise SiH₃NMe₂ (DMAS), SiH₃N(sec-Bu)₂ (DSBAS), SiH₂[NMe₂]₂ (BDMAS), SiH₂[NH(tert-Bu)]₂ (BTBAS), SiH₂[NEt₂]₂ (BDEAS), SiH[NMe₂]₃ (TDMAS), Si[NMe₂]₄ (TKDMAS), or the like, or combinations thereof. The applicable silicon precursors may be expressed as Si(NRᵢ)ₓ(H)₄₋ₓ, with “i” being equal to 1 or 2, and “x” being equal to 1, 2, 3, or 4. The symbol “R” represents an alkyl group such as a methyl group or an ethyl group.

In accordance with some embodiments, soaking process 76 may be performed for a period of time in the range between about 1 second and about 50 seconds per ALD cycle. The chamber pressure may be in the range between about 0.5 Torr and about 8 Torr. Also, process conditions such as the wafer temperature during the soaking process 76 is selected, so that the OH groups are readily broken off from dielectric liner 68A, while NH₂ groups that have already been attached are not broken off. For example, the soaking process may be performed at a wafer temperature in the range between about 70° C. and about 600° C. Soaking process 76 may be performed with plasma.

In the soaking process 76, the hydrogen atoms in the OH groups are broken off. the molecules of the silicon precursor also have bonds broken, and parts of the silicon precursor molecules are attached to the oxygen ions that remain on the surface of dielectric liner 68A. The attached parts are shown in FIG. 13, wherein the symbols with circles having “Si” therein represent the silicon precursor molecules. For example, When BDEAS is used, the bonds between Si and N in the BDEAS molecules are broken, and the parts of the BDEAS molecules including Si atoms are adsorbed on, and are attached to, the oxygen atoms.

The Si precursor prefers to attach to the oxygen in OH groups, and does not prefer to attach to NH₂ groups. Accordingly, the NH₂ groups act as the prohibitor for prohibiting the adsorption attachment of the silicon precursor. Since OH groups are attached to the bottoms of trenches 66, while NH₂ groups are attached to the top parts of dielectric liner 68A, the Si precursor is prohibited (at least partially) to be attached to the top parts of dielectric liner 68A, and are attached to the bottom parts of dielectric liner 68A. Accordingly, the adsorption of the silicon precursor is selective to the position. Also, from top to bottom of trenches 66, there is increasingly more silicon precursor attached, and the increase in the amount (per unit area of surface) of silicon precursor from top to bottom may be continuous.

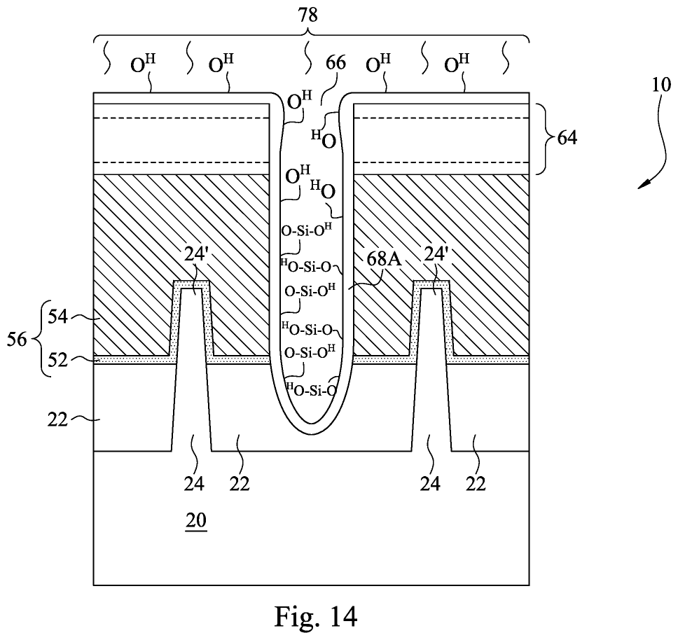

FIG. 14 illustrates an oxidation process 78 of the PEALD cycle 216. The respective process is illustrated as process 222 in the process flow 200 as shown in FIG. 24. In accordance with some embodiments, the oxidation process 78 is performed using an oxygen-containing gas comprising O₂, O₃, H₂O, or the like, or combinations thereof. The flow rate of the oxygen-containing gas may be in the range between about 1 slm and about 10 slm. The wafer temperature may be in the range between about 70° C. and about 600° C. The oxidation process is performed with plasma being generated.

As a result of the oxidation process, parts of the Si precursor are broken off, and Si atoms are attached with oxygen atoms to form silicon oxide. Furthermore, OH groups are further formed at the surface of the newly formed silicon oxide, as shown in FIG. 14. Meanwhile, the NH₂ groups are replaced with OH groups due to the existence of oxygen and hydrogen in the respective oxidation chamber.

The duration of the oxidation process 78 is long enough, so that all of the adsorbed silicon precursors are full oxidized from the top parts of trenches 66 to the bottom parts of trenches. This process is contrary to the process as shown in FIG. 12 since the process in FIG. 12 is a controlled process with lower parts being under-treated than the respective upper parts. In oxidation process 78, on the other hand, the duration for the oxidation process 78 is long enough until full oxidation is achieved. For example, the duration of oxidation process 78 may be in the range between about 0.2 seconds and about 6 seconds per ALD cycle.

It is appreciated that while silicon oxide is deposited selectively, after the oxidation process 78, the surface conditions of the exposed surfaces are similar to the surface conditions of the structure shown in FIG. 11, with OH groups being formed at the surface of the structure. Subsequently, the enhance PEALD cycle 216 as shown in FIGS. 12 through 14 are repeated, as also shown in the process flow 200 as in FIG. 24.

As aforementioned, the replacing rates of OH groups with NH₂ groups are increasingly higher in upper parts of trenches 66 than the respective lower parts of trenches 66. There are accordingly more NH₂ groups per unit surface area in upper parts of trenches 66 than the respective lower parts of trenches 66. Accordingly, the deposition rate of silicon oxide is higher in the lower parts of trenches than in the respective upper parts. This results in the deposition of silicon oxide to be in a bottom-up style. For example, at the bottom of trenches 66, a full atomic silicon oxide layer is grown. At the top of trenches 66 and outside of trenches 66, conversely, incubation delay occurs, and substantially no silicon oxide is grown, at least in the initial stages in the deposition of silicon oxide.

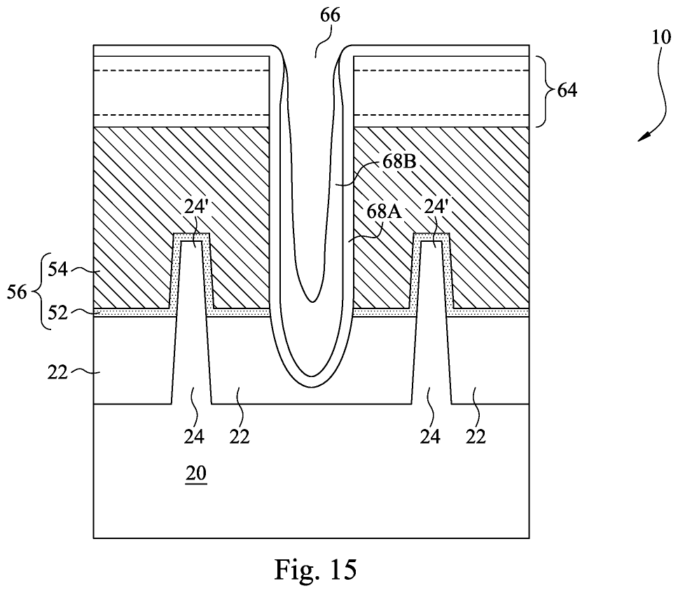

FIG. 15 illustrates an example structure after certain number of enhanced PEALD cycles 216 are performed, wherein from bottom to top of trenches 66, the deposited dielectric filling-region 68B is increasingly thinner. The top surface of dielectric filling-region 68B has a V-shape, making the subsequent deposition easier without causing seams.

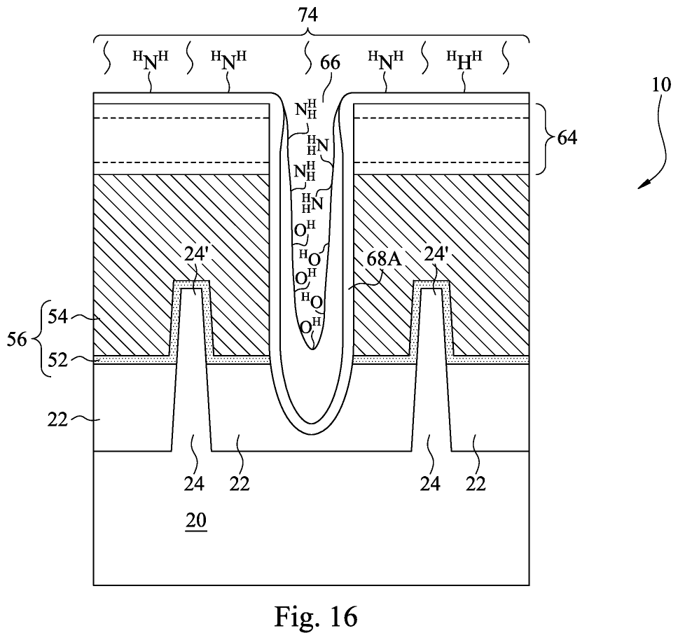

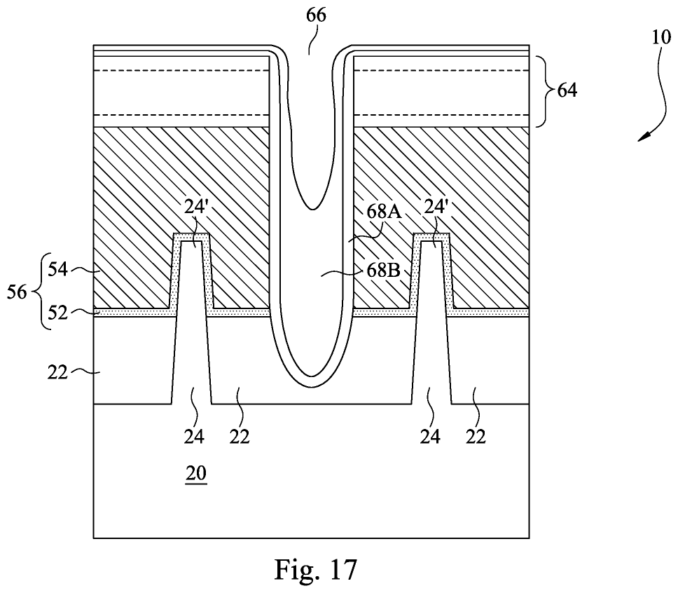

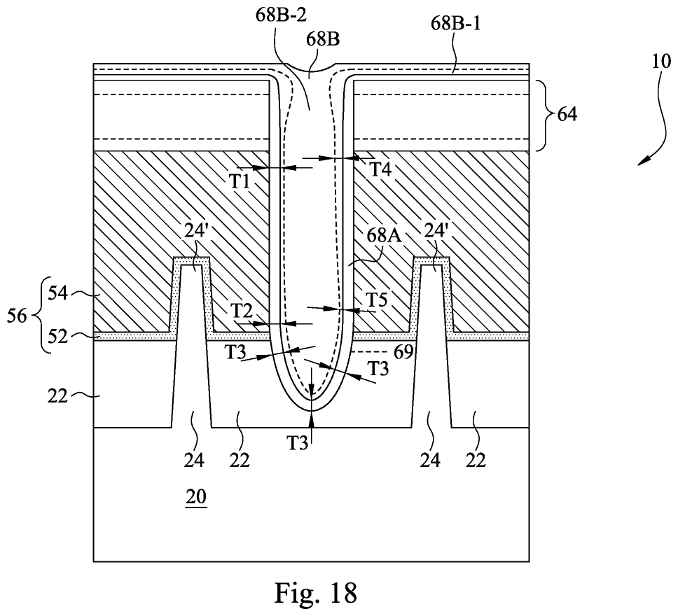

FIG. 16 illustrates the repeated treatment process 74 in a subsequent PEALD cycle 216. The treatment process 74 is essentially the same as the treatment process 74 as shown in FIG. 12. The OH groups are replaced with NH₂ groups, with upper parts of trenches 66 having higher replacing rates than the respective lower parts. Next, the silicon precursor soaking process 76 (FIG. 13) and oxidation process 78 (FIG. 14) are performed to finish another enhanced PEALD cycle 216. The repeated PEALD cycles 216 result in the bottom-up deposition of dielectric filling-region 68B, as shown in FIGS. 17 and 18, until trenches 66 are full filled.

It is appreciated that with dielectric filling-region 68B being increasingly thicker, trenches 66 become shallower. The difference in the replacing rates at the bottom and the top of trenches 66 becomes smaller. Eventually, when trenches 66 are shallow enough, no OH groups are replaced, regardless of their positions. The deposition of silicon oxide is thus unselective, and becomes conformal. Accordingly, the deposition of silicon oxide is highly selective in the beginning, and becomes less and less selective, until eventually becomes non-selective.

It is also appreciated that due to the oxygen plasma treatment process 78, the surface portions of dielectric liner 68A are also oxidized to form nitrogen-doped silicon oxide (SiON). Dielectric liner 68A thus becomes thinner due to the surface oxidation. Also, the deposited silicon oxide filling-region 68B protects, and reduces the oxidation rate of the respective underlying dielectric liner 68A. Since the upper parts of silicon oxide filling-region 68B are thinner than, and are deposited later than, the respectively lower parts, the upper parts of dielectric liner 68A are oxidized more, and the remaining dielectric liner 68A becomes thinner. The overhangs 70 (FIG. 11) may also disappear due to the high oxidation rate of dielectric liner 68A.

In FIG. 18, Dielectric liner 68A has thickness T1 at the top level of gate stack 56. Thickness T1 may be in the range between about 2 nm and about 4 nm. Thickness T1 is smaller than thickness T1′ (FIG. 11) measured before the deposition of dielectric-filling region 68B, wherein thickness T1′ may be in the range between about 3 nm and about 5 nm.

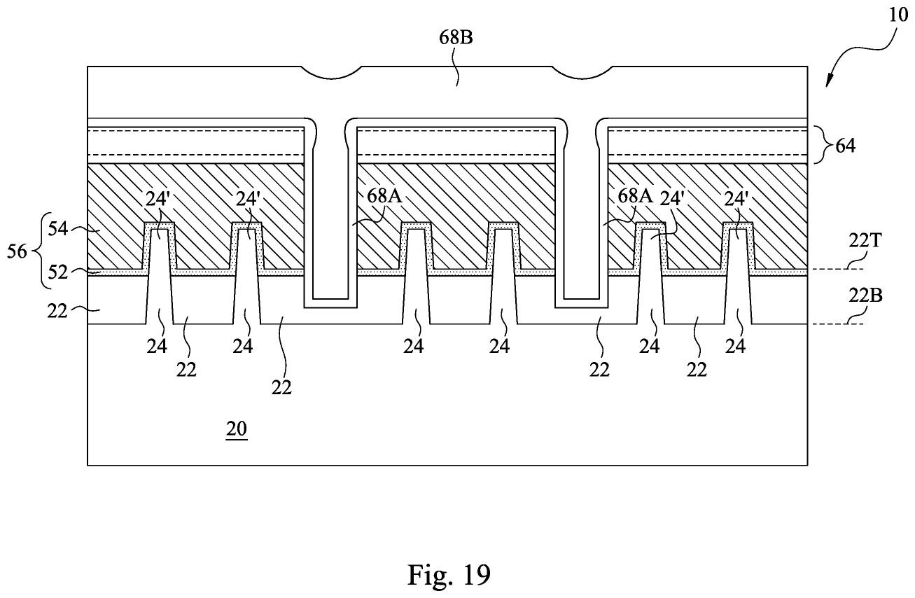

FIG. 19 illustrates the structure with trenches 66 fully filled with dielectric filling-region 68B, which may be silicon oxide. It is appreciated that the profiles of dielectric liner 68A and dielectric filling-region region 68B in FIG. 19 are schematic, and the details may be found referring to FIG. 18. It has been found that the dielectric filling-region 68B deposited in accordance with the embodiments of the present disclosure is substantially free from nitrogen therein, and is also free from seams therein. No nitrogen signal can be detected using detecting methods such as Energy-dispersive X-ray spectroscopy (EDS). The dielectric filling-region region 68B formed in accordance with the embodiments of the present disclosure is thus different from conventional seam-free dielectric regions formed using Flowable Chemical Vapor Deposition (FCVD), from which nitrogen signals can be detected.

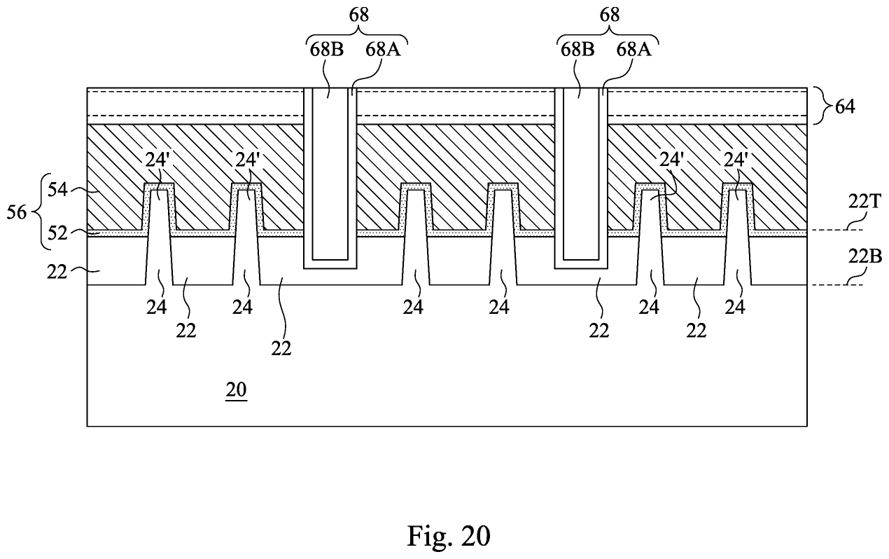

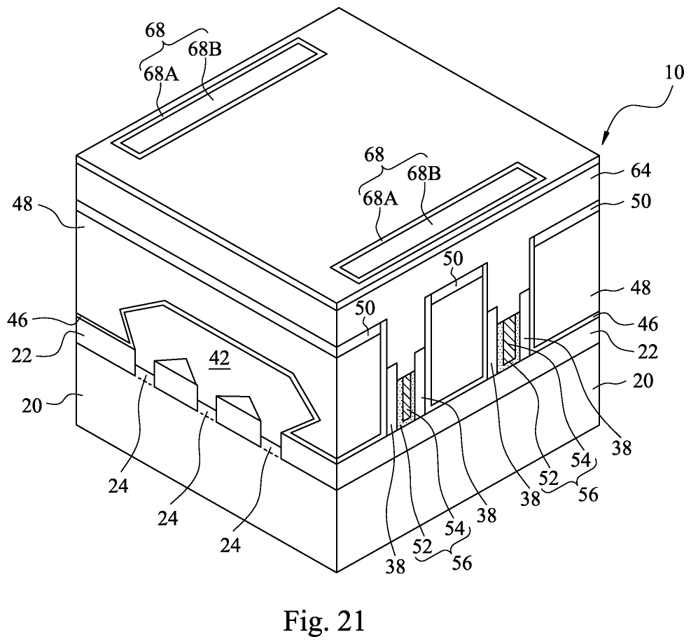

Referring to FIG. 20, A planarization process such as a CMP process or a mechanical grinding process is performed to remove the excess portions of dielectric liner 68A and dielectric filling-region 68B. The respective process is illustrated as process 224 in the process flow 200 as shown in FIG. 24. The remaining portions of dielectric liner 68A and dielectric filling-region 68B are collectively referred to as gate isolation regions 68 or CMG regions 68. FIG. 21 illustrates a perspective view of the structure including CMG regions 68.

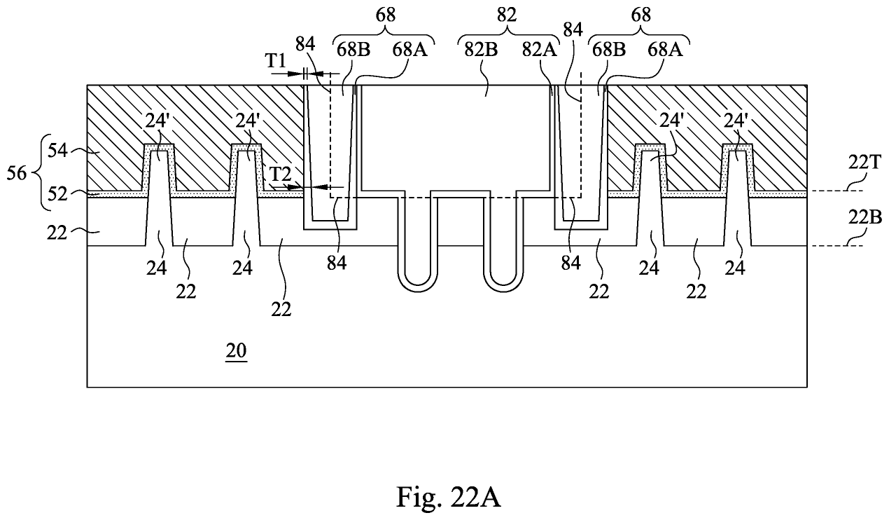

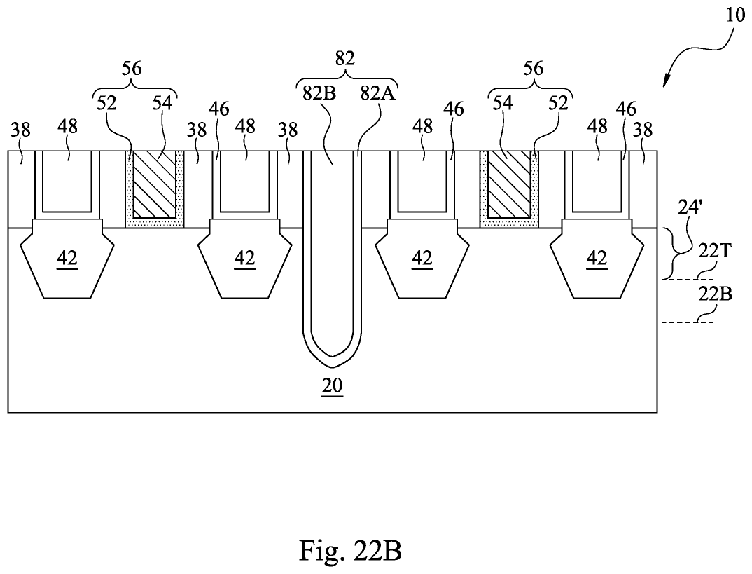

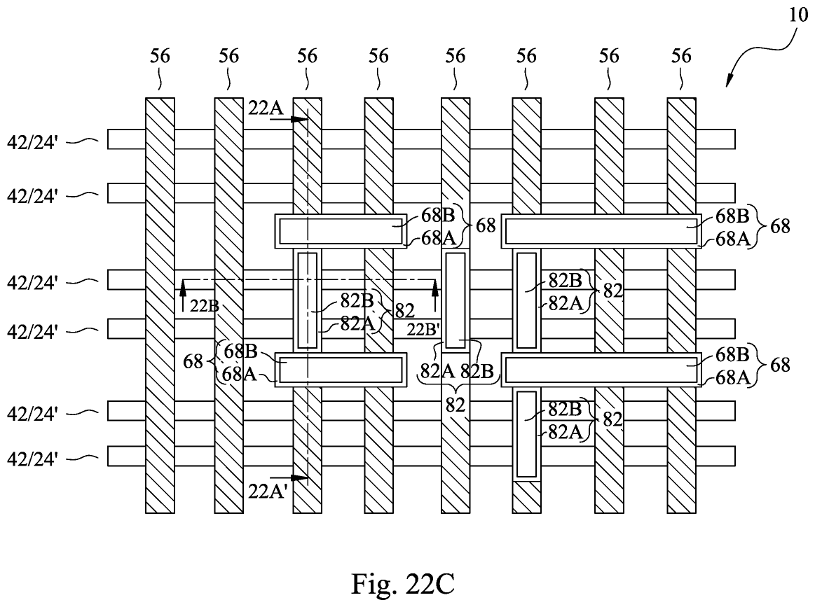

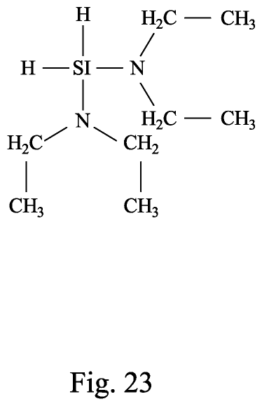

In subsequent processes, as shown in FIGS. 22A, 22B, and 22C, fin isolation regions (also referred to as CMODE regions) 82 are formed. The respective process is illustrated as process 226 in the process flow 200 as shown in FIG. 24. In the formation process, protruding semiconductor fins 24′ and the underlying semiconductor strips 24 are etched to form trenches, which are then filled with dielectric materials to form fin isolation regions 82. In accordance with some embodiments, fin isolation regions 82 may also include dielectric liner 82A formed of silicon nitride and dielectric filling-region 82B formed of silicon oxide. Dielectric liner 82A and dielectric filling-region 82B may be formed using the same processes and same materials as dielectric liner 68A and dielectric filling-region 68B, respectively. The details are thus not repeated herein.

FIG. 22C illustrates a top view of a part of wafer 10. It is appreciated that FIG. 22C schematically illustrates how gate isolation regions 68 and fin isolation regions 82 may cut gate stack and fins, and the actual layout in the formation of production wafers may be more complicated. FIG. 22A illustrates the cross-section 22A-22A′ as shown in FIG. 22C, and FIG. 22B illustrates the cross-section 22B-22B′ as shown in FIG. 22C.

Referring to FIG. 22A, due to the oxidation of dielectric liner 68A during the deposition of dielectric filling-region 68B, the upper parts of dielectric liner 68A may be thinner than the respective lower parts. This is contrary to the situation before the deposition of dielectric filling-region 68B, wherein the dielectric liner 68A have thicker upper parts and thinner lower parts, as shown in FIG. 12. For example, in FIG. 22A, dielectric liner 68A has thickness T1 at the top level of gate stack 56, and thickness T2 at the bottom level of gate stack 56. Thickness T1 may be smaller than thickness T2. In accordance with some embodiments, thickness ratio T1/T2 may be in the range between about 0.3 and about 0.8.

In accordance with some embodiments, from the top level of gate stack 56 to a certain lower level 69 (FIG. 18) of gate stack 56, the thicknesses of dielectric liner 68A may gradually reduce. Below level 69, the thicknesses of dielectric liner 68A may be uniform. For example, FIG. 18 illustrates that from level 69 to the very bottom portion of dielectric liner 68A, dielectric liner 68A has uniform thickness T3.

As discussed above, some portions of dielectric liner 68A are oxidized during the deposition of dielectric filling-region 68B, and thicker portions of the upper portions of dielectric liner 68A are oxidized than the respective lower portions. Accordingly, as also shown in FIG. 18, dielectric filling-region 68B includes outer portion 68B-1, which comprises SiON due to the oxidation of silicon nitride, and inner portion 68B-2, which includes the silicon oxide deposited using enhanced PEALD, and which is free from nitrogen therein.

In accordance with some embodiments, the SiON layer 68B-1 has thickness T4 at the top level of gate stack 56, and thickness T5 at the bottom level of gate stack 56. Thickness T5 is smaller than thickness T4 due to the less oxidation. SiON layer 68B-1 may also have overhangs due to the increased oxidation at corners. Also, the SiON layer 68B-1 may have increasingly greater thicknesses from the bottom level to the top level of gate stack 56. In addition, from level 69 downwardly, the thicknesses of SiON layer 68B-1 may be substantially uniform.

As shown in FIG. 22A, fin isolation region 82 may be in contact with dielectric liner 68A. in accordance with alternative embodiments, in the formation of fin isolation region 82, gate isolation regions 68 are also patterned. Fin isolation region 82 may thus extend into CMG regions 68, and may be in contact with dielectric-filling region 68B. Dashed lines 84 illustrate the corresponding boundaries of fin isolation region 82.

In accordance with some embodiments, the formation of CMG regions 68 is bottom-up, with the top surface of gate isolation regions 68 in the trenches having V-shaped top surface. The quality of the resulting dielectric filling-region 68B is thus improved, and no seam is formed. Experiments have been performed to form a first sample wafer and a second sample wafer. In the first sample wafer, dielectric-filling region 68B is formed using PEALD, without the NH₃ treatment process. Accordingly, the corresponding dielectric-filling regions 68B have seams. Metal may adversely be filled into the seams in subsequent processes, and cause the shorting of neighboring source/drain contacts on opposite ends of the gate isolation regions. The low quality of the dielectric-filling region 68B may also be revealed by etching the first sample using acetic acid and ammonium fluoride for 10 seconds, wherein large voids are generated in the middle of the corresponding dielectric-filling region. This indicates that the quality and the density of the dielectric-filling region are low.

As a comparison, in the second sample wafer, dielectric-filling regions 68B are formed according to the embodiments of the present disclosure. Accordingly, the corresponding dielectric-filling regions 68B have no seams. When etching the second sample using acetic acid and ammonium fluoride for 10 seconds, no void is formed in dielectric-filling region 68B. This indicates that the quality and the density of the dielectric-filling region 68B are high.

The embodiments of the present disclosure have some advantageous features. By using ammonia to treat the surface of silicon nitride liner and to generate the difference in the number and the percentage of attached NH₂ groups between upper parts and lower parts of trenches, bottom-up deposition may be achieved in the filling of the trenches with silicon oxide, and the quality of the resulting dielectric regions is improved.

In accordance with some embodiments, a method comprises etching a gate stack to form a trench; depositing a silicon nitride liner extending into the trench; and depositing a silicon oxide layer on the silicon nitride liner, the depositing the silicon oxide layer comprising performing a treatment process using a process gas comprising nitrogen and hydrogen; and performing a soaking process on the wafer using a silicon precursor. In an embodiment, the process gas comprises a nitrogen gas (N₂) and a hydrogen gas (H₂). In an embodiment, the process gas comprises ammonia (NH₃). In an embodiment, the process gas comprises both of ammonia and hydrogen (H₂). In an embodiment, the treatment process comprises replacing OH groups at trench top of the trench with NH-comprising groups.

In an embodiment, from a trench bottom to the trench top of the trench, replacing rates gradually increase, wherein the replacing rates are percentages of replacing the OH groups with NH₂ groups. In an embodiment, at a time the treatment process is stopped, substantially all OH groups at the trench bottom are unreplaced with NH₂ groups. In an embodiment, at the time the treatment process is stopped, substantially all OH groups at the trench top are replaced with NH₂ groups. In an embodiment, the method further comprises, after the soaking process, performing an oxidation process on the silicon precursor that is adsorbed to the silicon nitride liner. In an embodiment, the oxidation process is controlled so that from trench top to trench bottom of the trench, substantially all adsorbed silicon-containing groups from the silicon precursor are converted as silicon oxide.

In accordance with some embodiments, a structure comprises a first gate stack and a second gate stack; and a gate isolation region between the first gate stack and the second gate stack, wherein the gate isolation region comprises opposite sidewalls contacting the first gate stack and the second gate stack, and wherein the gate isolation region comprises a silicon nitride liner comprising a first portion contacting the first gate stack, wherein the first portion has a first thickness measured from a top level of the first gate stack, and a second thickness measured from a bottom level of the first gate stack, and wherein the first thickness is smaller than the second thickness; a second portion; and a bottom portion connecting the first portion to the second portion; and a silicon oxide region between the first portion and the second portion, wherein the silicon oxide region overlaps the bottom portion of the silicon nitride liner.

In an embodiment, a ratio of the first thickness to the second thickness is smaller than about 0.8. In an embodiment, the ratio of the first thickness to the second thickness is in a range between about 0.3 and about 0.8. In an embodiment, at least a center portion of the silicon oxide region is free from nitrogen therein. In an embodiment, the silicon nitride liner has a third thickness at a level lower than the bottom level of the first gate stack, and a bottommost part of the silicon nitride liner has a fourth thickness equal to the third thickness. In an embodiment, the structure further comprises a shallow trench isolation region underlying and contacting the first gate stack and the gate isolation region; and a fin isolation region comprising a first portion on a side of, and is in contact with, the gate isolation region; and a second portion penetrating through the shallow trench isolation region.

In accordance with some embodiments, a structure comprises a semiconductor substrate; a plurality of dielectric isolation regions in the semiconductor substrate; a first semiconductor fin and a second semiconductor fin extending higher than the plurality of dielectric isolation regions; a first gate stack and a second gate stack on the first semiconductor fin and the second semiconductor fin, respectively; and a gate isolation region separating the first gate stack from the second gate stack, wherein the gate isolation region comprises a silicon nitride liner comprising a portion contacting a sidewall of the first gate stack, wherein the portion has a first thickness measured from a first top surface level of the first gate stack, and a second thickness measured from a second top surface level of one of the plurality of dielectric isolation regions, and wherein from the first top surface level to the second top surface level, thicknesses of the portion of the silicon nitride liner increase gradually.

In an embodiment, the structure further comprises a silicon oxide region contacting the portion of the silicon nitride liner. In an embodiment, a center portion of the silicon oxide region is free from oxygen therein. In an embodiment, a ratio of the first thickness to the second thickness is in a range between about 0.3 and about 0.8.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
etching a gate stack to form a trench;
depositing a silicon nitride liner extending into the trench; and
depositing a silicon oxide layer on the silicon nitride liner, the depositing the silicon oxide layer comprising:
performing a treatment process using a process gas comprising nitrogen and hydrogen; and
performing a soaking process using a silicon precursor.

2. The method of claim 1, wherein the process gas comprises a nitrogen gas (N₂) and a hydrogen gas (H₂).

3. The method of claim 1, wherein the process gas comprises ammonia (NH₃).

4. The method of claim 3, wherein the process gas comprises both of ammonia and hydrogen (H₂).

5. The method of claim 1, wherein the treatment process comprises replacing OH groups at trench top of the trench with NH-comprising groups.

6. The method of claim 5, wherein from a trench bottom to the trench top of the trench, replacing rates gradually increase, wherein the replacing rates are percentages of replacing the OH groups with NH₂ groups.

7. The method of claim 6, wherein at a time the treatment process is stopped, substantially all OH groups at the trench bottom are unreplaced with NH₂ groups.

8. The method of claim 7, wherein at the time the treatment process is stopped, substantially all OH groups at the trench top are replaced with NH₂ groups.

9. The method of claim 1 further comprising, after the soaking process, performing an oxidation process on the silicon precursor that is adsorbed to the silicon nitride liner.

10. The method of claim 9, wherein the oxidation process is controlled so that from trench top to trench bottom of the trench, substantially all adsorbed silicon-containing groups from the silicon precursor are converted as silicon oxide.

11. A structure comprising:
a first gate stack and a second gate stack; and
a gate isolation region between the first gate stack and the second gate stack, wherein the gate isolation region comprises opposite sidewalls contacting the first gate stack and the second gate stack, and wherein the gate isolation region comprises:
a silicon nitride liner comprising:
a first portion contacting the first gate stack, wherein the first portion has a first thickness and a second thickness different from the first thickness, and wherein the first thickness and the second thickness are measured at different levels of the first gate stack;
a second portion; and
a bottom portion connecting the first portion to the second portion; and
a silicon oxide region between the first portion and the second portion, wherein the silicon oxide region overlaps the bottom portion of the silicon nitride liner.

12. The structure of claim 11, wherein the first thickness is smaller than the second thickness.

13. The structure of claim 12, wherein a ratio of the first thickness to the second thickness is in a range between about 0.3 and about 0.8.

14. The structure of claim 11, wherein at least a center portion of the silicon oxide region is free from nitrogen therein.

15. The structure of claim 11, wherein the silicon nitride liner has a third thickness at a level lower than a bottom level of the first gate stack, and a bottommost part of the silicon nitride liner has a fourth thickness substantially equal to the third thickness.

16. The structure of claim 11 further comprising:
a shallow trench isolation region underlying and contacting the first gate stack and the gate isolation region; and
a fin isolation region comprising:
a first part on a side of, and is in contact with, the gate isolation region; and
a second part penetrating through the shallow trench isolation region.

17. A structure comprising:
a semiconductor substrate;
a plurality of dielectric isolation regions in the semiconductor substrate;
a first semiconductor fin and a second semiconductor fin extending higher than the plurality of dielectric isolation regions;
a first gate stack and a second gate stack on the first semiconductor fin and the second semiconductor fin, respectively; and
a gate isolation region separating the first gate stack from the second gate stack, wherein the gate isolation region comprises:
a silicon nitride liner comprising a portion contacting a sidewall of the first gate stack, wherein the portion has a first thickness measured from a first top surface level of the first gate stack, and a second thickness measured from a second top surface level of one of the plurality of dielectric isolation regions, and wherein from the first top surface level to the second top surface level, thicknesses of the portion of the silicon nitride liner increase.

18. The structure of claim 17 further comprising a silicon oxide region contacting the portion of the silicon nitride liner.

19. The structure of claim 18, wherein a center portion of the silicon oxide region is free from oxygen therein.

20. The structure of claim 17, wherein a ratio of the first thickness to the second thickness is in a range between about 0.3 and about 0.8.
